(19) United States
(12) Patent Application Publication
(10) Pub. No.: US 2024/0223980 A1
(43) Pub. Date: Jul. 4, 2024

(54) TRANSDUCER EXCURSION CORRECTION

(71) Applicant: Google LLC, Mountain View, CA (US)

(72) Inventors: Lei Chen, Taipei (TW); Yahsin Chou, Taipei City (TW); Shin-Horng Chen, Taipei City (TW)

(21) Appl. No.: 17/996,263

(22) PCT Filed: Oct. 13, 2021
(86) PCT No.: PCT/US2021/054770

§ 371 Date: Oct. 14, 2022

(51) Int. Cl. H04R 29/00; G01R 19/12; H04R 3/00

(52) U.S. Cl. CPC H04R 29/003; G01R 19/12; H04R 3/007; H04R 2499/11

(57) ABSTRACT

In general, various aspects of the techniques are directed to transducer excursion correction. A computing device comprising a memory and a processor may be configured to perform the techniques. The memory may store voltage measurements representative of voltage across a transducer and current measurements representative of current through the transducer. The processor may identify a first voltage measurement of the voltage measurements and a first current measurement of the current measurements associated with nonlinear vibration of the transducer. The processor may perform a principal component analysis with respect to the first voltage measurement and the first current measurement to obtain a principal component representative of variation of the voltage across and the current through the transducer. The processor may modify, based on the principal component, an input voltage to be applied across the transducer to reduce the nonlinear vibration of the transducer.

### BACKGROUND

Computing devices may include an electroacoustic transducer to convert electrical energy into sound, which may also be referred to as a speaker or loudspeaker. The speaker may include a diaphragm (which may also be referred to as a cone due to such diaphragms being conically shaped) and a coil, where the coil is attached to the cone. The speaker also includes a magnet to produce a magnetic field in a gap between the cone and the back of the speaker. An input voltage may drive the coil (usually via inductance) that causes the coil to move in the presence of the magnetic field and thereby move the cone to produce sound waves.

Most speakers feature some form of direct current (DC) offset in which excursion of the cone occurs asymmetrically (meaning, the cone moves more in one direction than in the other). Some DC offset may occur due to a mechanical design of the transducer or as a result of the manufacturing process. Additionally, DC offset may occur due to differences in the air-load in the front and back cavity of the transducer. Given that design and manufacturer of most speakers used in computing devices is fairly well controlled, most DC offset in such speakers may occur due to asymmetry in the nonlinear characteristics of the electrical and mechanical parameters of the speaker. For example, nonlinear characteristics may include magnetic force factor, suspension stiffness (e.g., for the coil and/or cone), and/or inductance of the transducer.

To compensate for DC offset, particularly at large input voltages that result in more extensive excursion, computing devices may attempt to model DC offset. Such DC offset modeling is difficult however due to the nonlinear nature of such DC offset and the various different types of DC offset that may vary, not only between different models and/or types of speakers, but also between two of the same model and type of speakers. Moreover, such modeling is complex (in terms of processing resources, memory, memory bandwidth, and the like) but may enable compensating measures to be taken so as to prevent distortion and/or noise, while also possibly protecting the speaker from damage (e.g., tearing the cone due to excursion occurring beyond an excursion limit).

### SUMMARY

In general, this disclosure describes techniques that may enable transducer excursion correction that compensates for direct current (DC) offset without possibly requiring complex DC offset modeling. For example, a computing device may measure a voltage across and current through the transducer and perform a principal component analysis (PCA) with respect to the voltage and current measurements to identify principal components representative of a maximum variation and a minimum variation of the voltage across and the current through the transducer. These maximum and minimum variation of the voltage across and the current through the transducer may facilitate identification of a nonlinear slope that is representative of the DC offset for the particular transducer. The computing device may then modify, or in other words, adapt the input voltage to be applied across the transducer m order to reduce nonlinear vibration by the transducer (that would otherwise occur due to the DC offset).

In this way, techniques of this disclosure may enable the computing device to more efficiently identify DC offset (e.g., nonlinear excursion) and perform transducer excursion correction to reduce the impact of DC offset, thereby potentially reducing distortion and/or noise during playback of audio by the transducer (which may also be referred to as a speaker) while also possibly protecting the transducer from damage. Further, as DC offset is identified without possibly resorting to complex DC offset modeling (e.g., by using a principal component analysis to identify the nonlinear slope representative of nonlinear excursions), the computing device may more efficiently (compared to the complex DC modeling) correct for transducer excursions in a manner that improves operation of the computing device itself (e.g., consumes less processor cycles, memory, memory bandwidth, and accompanying power).

In one example, various aspects of the techniques are directed to a method comprising, obtaining, by one or more processors of a computing device, a plurality of voltage measurements representative of voltage applied across a transducer over a period of time; obtaining, by the one or more processors, a plurality of current measurements representative of current through the transducer over the period of time; identifying, by the one or more processors, at least one first voltage measurement of the plurality of voltage measurements and at least one first current measurement of the plurality of current measurements associated with nonlinear vibration of the transducer; performing, by the one or more processors, a principal component analysis respect at least one first voltage measurement and the at least one first current measurement to obtain a principal component representative of a maximum variation of the voltage across and the current through the transducer; and modifying, by the one or more processors, and based on the principal component, an input voltage to be applied across the transducer to reduce the first vibration of the transducer.

In another example, various aspects of the techniques are directed to a computing device comprising: a memory configured to store a plurality of voltage measurements representative of a voltage across a transducer over a period of time and a plurality of current measurements representative of current through the transducer over the period of time; and one or more processors configured to: identify at least one first voltage measurement of the plurality of voltage measurements and at least one first current measurement of the plurality of current measurements associated with nonlinear vibration of the transducer; perform a principal component analysis with respect to the at least one first voltage measurement and the at least one first current measurement to obtain a principal component representative of a maximum variation of the voltage across and the current through the transducer, and modify, based on the principal component, an input voltage to be applied across the transducer to reduce the nonlinear vibration of the transducer.

In another example, various aspects of the techniques are directed to a non-transitory computer-readable storage medium having stored thereon instructions that, when executed, cause one or more processors of a computing device to, obtain a plurality of voltage measurements representative of a voltage across a transducer over a period of time; obtain a plurality of current measurements representative of current through the transducer over the period of time; identify at least one first voltage measurement of the plurality of voltage measurements and at least one first current measurement of the plurality of current measurements associated with nonlinear vibration of the transducer; perform a principal component analysis with respect to the at least one first voltage measurement and the at least one first current measurement to obtain a principal component representative of a maximum variation of the voltage across and the current through the transducer, and modify, based on the principal component, an input voltage to be applied across the transducer to reduce the nonlinear vibration of the transducer.

In another example, various aspects of the techniques are directed to a computing device comprising: means for obtaining a plurality of voltage measurements representative of a voltage across a transducer over a period of time and a plurality of current measurements representative of current through the transducer over the period of time; means for identifying at least one first voltage measurement of the plurality of voltage measurements and at least one first current measurement of the plurality of current measurements associated with nonlinear vibration of the transducer; means for performing a principal component analysis with respect to the at least one first voltage measurement and the at least one first current measurement to obtain a principal component representative of a maximum variation of the voltage across and the current through the transducer; and means for modifying, based on the principal component, an input voltage to be applied across the transducer to reduce the nonlinear vibration of the transducer.

### BRIEF DESCRIPTION OF DRAWINGS

FIG. 1 is a block diagram illustrating an example computing device that is configured to perform speaker excursion correction in accordance with one or more aspects of the present disclosure.

FIG. 2 is conceptual circuit diagram of an example transducer for which transducer correction may be performed in accordance with various aspects of the transducer exertion correction techniques described in this disclosure.

FIG. 3 is a diagram illustrating a graph of an example current-voltage distribution from which principal components are extracted to support various aspects of the transducer excursion correction techniques described in this disclosure.

FIG. 4 is another diagram illustrating a graph of an example current-voltage distribution from which principal components are extracted to support various aspects of the transducer excursion correction techniques described in this disclosure.

FIG. 5 is a diagram illustrating four graphs showing example results of performing various aspects of the transducer excursion correction techniques described in this disclosure.

FIG. 6 is a diagram illustrating two graphs showing additional example results of performing various aspects of the transducer excursion correction techniques described in this disclosure.

FIG. 7 is a flowchart illustrating exemplary operation of the computing device shown in FIG. 1 in performing various aspects of the transducer excursion correction techniques.

### DETAILED DESCRIPTION

In general, this disclosure describes a computing device configured to correct for direct current (DC) offset in a transducer that occurs due to various factors, such as asymmetry in the nonlinear characteristics of the electrical and mechanical parameters of the transducer. Nonlinear characteristics may include magnetic force factor, suspension stiffness (e.g., for a coil and/or cone of the transducer), and/or inductance of the transducer. Such DC offset may refer to excursion of the cone that occurs in one direction (e.g., out) more than another direction (e.g., in), resulting in nonlinear vibration that may produce noise or other artifacts as the transducer (which may also be referred to as a speaker or loudspeaker) vibrates in order to reproduce a soundfield.

Rather than create a model of the DC offset for a particular speaker, the computing device may identify DC offset indirectly via a principal component analysis (PCA). That is, the computing device may measure voltage across and current through the transducer and perform a principal component analysis (PCA) with respect to the voltage and current measurements to identify principal components represent e of a maximum variation and a minimum variation of the voltage across and the current through the transducer. These maximum and mint n variation of the voltage across and the current through the transducer may facilitate identification of a nonlinear slope (as compared to a target slope that a designer of the speaker may identify or which may be learned via machine learning or other processes) that is representative of the DC offset for the particular transducer. The computing device may then modify, or in other words, adapt the input voltage to be applied across the transducer in order to reduce nonlinear vibration by the transducer (that would otherwise occur due to the DC offset).

In this way, techniques of this disclosure may enable the computing device to more efficiently identify DC offset (e.g, nonlinear excursion) and perform transducer excursion correction to reduce the impact of DC offset, thereby potentially reducing distortion and/or noise during playback of audio by the transducer (which may also be referred to as a speaker) while also possibly protecting the transducer from damage. Farther, as DC offset is identified without possibly resorting to complex DC offset modeling (e.g., by using a principal component analysis to identify the nonlinear slope representative of nonlinear excursions), the computing device may more efficiently (compared to the complex DC modeling) correct for transducer excursions in a manner that improves operation of the computing device itself (e.g., consumes less processor cycles, memory, memory bandwidth, and accompanying power).

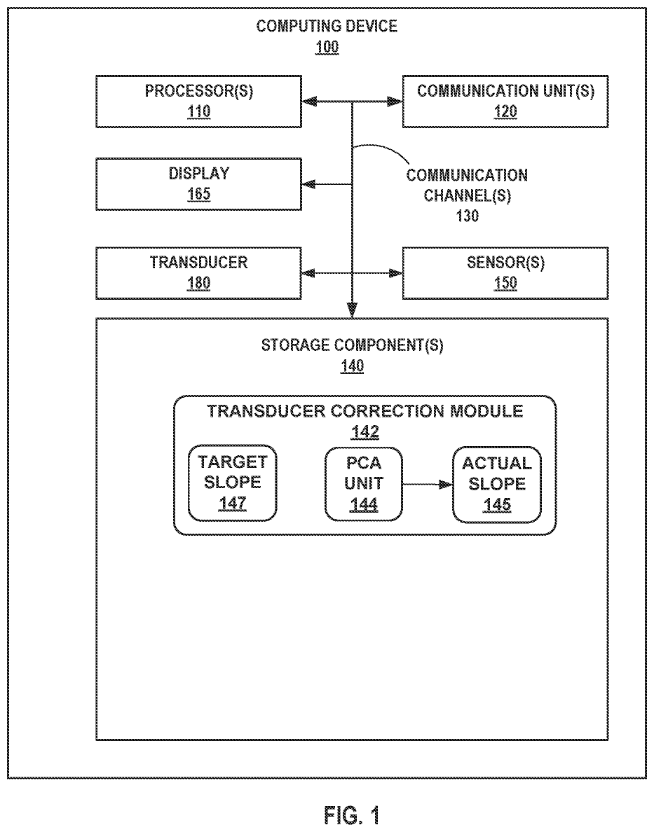

FIG. 1 is a block diagram illustrating an example computing device that is configured to provide visual communication via edge lighting about a status change of the example computing device, in accordance with one or more aspects of the present disclosure. FIG. 1 illustrates only one particular example of computing device 100, and many other examples of computing device 100 may be used in other instances and may include a subset of the components included in computing device 100 or may include additional components not shown in FIG. 1.

As shown in the example of FIG. 1, computing device 100 includes one or more processors 110, one or more communication unit(s) 120, one or more sensor(s) 150, one or more storage component(s) 140, a display 165, and a transducer 180. Communication channel(s) 130 interconnect each of the components 110, 120, 140, 150, and 165 for inter-component communications (physically, communicatively, and/or operatively). In some examples, communication channel(s) 130 may include a system bus, a network connection, an inter-process communication data structure, or any other method for communicating data.

One or more communication unit(s) 120 communicate with external devices via one or more wired and/or wireless networks by transmitting and/or receiving network signals on the one or more networks. Examples of communication unit(s) 120 include a network interface card (e.g., an Ethernet card), an optical transceiver, a radio frequency transceiver, a GPS receiver, or any other type of device that can send and/or receive information. Other examples of communication unit(s) 120 may include short wave radios, cellular data radios, wireless network radios, as well as universal serial bus (USB) controllers.

One or more sensor(s) 150 may receive input. Examples of sensor(s) 150 include, but are not limited to, a capacitive touchscreen, a projective capacitive touchscreen, a resistive touchscreen, a surface acoustic wave touchscreen, a camera, a microphone, a button, a switch, an accelerometer, a gyroscope, a barometer, a magnetometer, a radar, etc. Sensor(s) 150 may receive input, such as radio wave input, in conjunction with communication unit(s) 120 (e.g., a UWB interface, a personal area network (PAN) interface, a global positioning system (GPS) receiver, a radar detector, etc.).

One or more storage component(s) 140 store information for processing during operation of computing device 100. In some examples, storage component(s) 140 may represent a temporary memory, meaning that a primary purpose of storage component(s) 140 is not long-term storage. Storage component(s) 140 on computing device 100 may be configured for short-term storage of information as volatile memory and therefore may not retain stored contents if powered off. Examples of volatile memories include random-access memories (RAM), dynamic random-access memories (DRAM), static random-access memories (SRAM), and other forms of volatile memories known in the art.

Storage component(s) 140, in some examples, also include one or more computer-readable storage media, including in some examples one or more non-transitory computer-readable storage mediums. Storage component(s) 140 may be configured to store larger amounts of information than typically stored by volatile memory. Storage component(s) 140 may further be configured for long-term storage of information as non-volatile memory space and retain information after power on/off cycles. Examples of non-volatile memories include magnetic hard discs, optical discs, floppy discs, flash memories, or forms of electrically programmable memories (EPROM) or electrically erasable and programmable (EEPROM) memories. Storage component(s) 140 may store program instructions and/or information (e.g., data) associated with a transducer correction module 142.

One or more processors 110 may implement functionality and/or execute instructions associated with computing device 100. Examples of processors 110 include application processors, display controllers, auxiliary processors, one or more sensor hubs, and any other hardware configured to function as a processor, a processing unit, or a processing device. Transducer correction module 142 may represent instructions that are operable by processors 110 to perform various actions, operations, or functions of computing device 100. For example, processors 110 may retrieve and execute instructions stored by storage component(s) 140 that cause processors 110 to perform the operations described herein that are attributed to transducer correction module 142. The instructions, when executed by processors 110, may cause computing device 100 to store information within storage component(s) 140, for example, transducer correction module 142.

Display 165 may represent any type of device capable of presenting information in visual form. Display 165 may include a frame buffer or other local memory into which display data (e.g., pixel data) is loaded, and a dedicated display processor that performs various operations to cause display 165 to present the pixel data. Examples of display 165 may include one or more of a liquid crystal display (LCD), a light-emitting diode (LED) display, an organic LED (OLED) display, an active-matrix OLED (AMOLED) display, a plasma display, a quantum dot LED (QLED) display, etc.

Transducer 180 may represent an electroacoustic transducer that is configured to onvert electrical energy into sound. Transducer 180 may also be referred to as a speaker 180 or a loudspeaker 180. Computing device 100 may, in some instances, include a housing (not shown in the example of FIG. 1) that encompasses or otherwise houses speaker 180 (where speaker 180 may be, in this instance, referred to as an internal speaker 180). In other examples, speaker 180 may be electrically coupled to transducer 180 but external to the housing of computing device 100 (where speaker 180 may, in these instances, be referred to as an external speaker 180).

In either instance, speaker 180 may include a diaphragm (which may also be referred to as a cone due to such diaphragms being conically shaped) and a coil, where the coil is attached to the cone. Speaker 180 may also include a magnet to produce a magnetic field in a gap between the cone and the back of speaker 180. An input voltage may drive the coil (usually via inductance) that causes the coil to move in the presence of the magnetic field and thereby move the cone to produce sound waves. Modulating the input voltage may result in modulation of the sound waves to recreate a soundfield.

Most speakers, including speaker 180, feature some form of direct current (DC) offset in which excursion of the cone occurs asymmetrically (meaning, the cone moves more in one direction than in the other). Some DC offset may occur due to a mechanical design of the transducer or as a result of the manufacturing process. Additionally, DC offset may occur due to differences in the air-load in the front and back cavity of the transducer. Given that design and manufacturer of most speakers used computing devices, such as computing device 100, is fairly well controlled, most DC offset in such speakers may occur due to asymmetry in the nonlinear characteristics of the electrical and mechanical parameters of the speaker. For example, nonlinear characteristics may include magnetic force factor, suspension stiffness (e.g. for the coil and/or cone), and/or inductance of the transducer.

To compensate for DC offset, particularly at large input voltages that result in more extensive excursion, computing devices may attempt to model DC offset. Such DC offset modeling is difficult however due to the nonlinear nature of such DC offset and the various different types of DC offset that may vary, not only between different models and/or types of speakers, but also between two of the same model and type of speakers. Moreover, such modeling is complex (in tens of processing resources, memory, memory bandwidth, and the like) but may enable compensating measures to be taken so as to prevent distortion and/or noise, while also possibly protecting the speaker from damage (e.g., tearing the cone due to excursion occurring beyond an excursion limit).

In accordance with various aspects of the techniques described in this disclosure, computing device 100 may be configured to perform transducer excursion correction that compensates for DC offset without possibly requiring complex DC offset modeling. For example, computing device 100 include a transducer correction module 142 that processor 110 may invoke when driving speaker 180. Transducer correction module 142 may measure a voltage across and current through speaker 180 and perform a principal component analysis (PCA) with respect to the voltage and current measurements to identify principal components representative of maximum variation and a minimum variation of the voltage across and the current through speaker 180. These maximum and minimum variation of the voltage across and the current through speaker 180 may facilitate identification of a nonlinear slope that is representative of the DC offset for speaker 180. Transducer correction module 142 may then modify, or in other words, adapt the input voltage to be applied across speaker 180 in order to reduce nonlinear vibration by speaker 180 (that would otherwise occur due to the DC offset).

In operation, transducer correction module 142 may obtain the voltage measurement representative of a voltage across speaker 180 over a period of time (e.g., some sampling period, such as a previous number of seconds). Transducer correction module 142 may apply, as one example, a moving window sampling approach continually updating such measurements as time progresses to maintain a constant number of measurements or via any other way by which to measure such voltage over a period of time. Transducer correction module 142 may obtain the voltage measurements from storage components 140 and/or directly from speaker 180. Transducer correction module 142 may also obtain the current measurement representative of a current through the transducer, again either from storage components 140 and/or directly from speaker 180, for the same period of time and in a similar manner to how the voltage measurements are obtained.

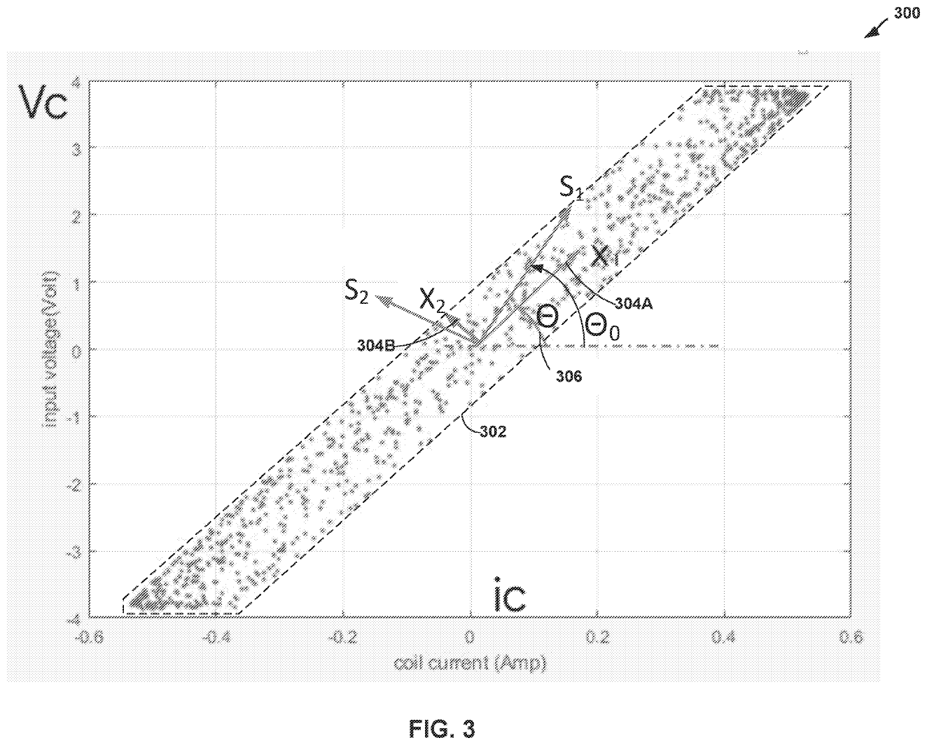

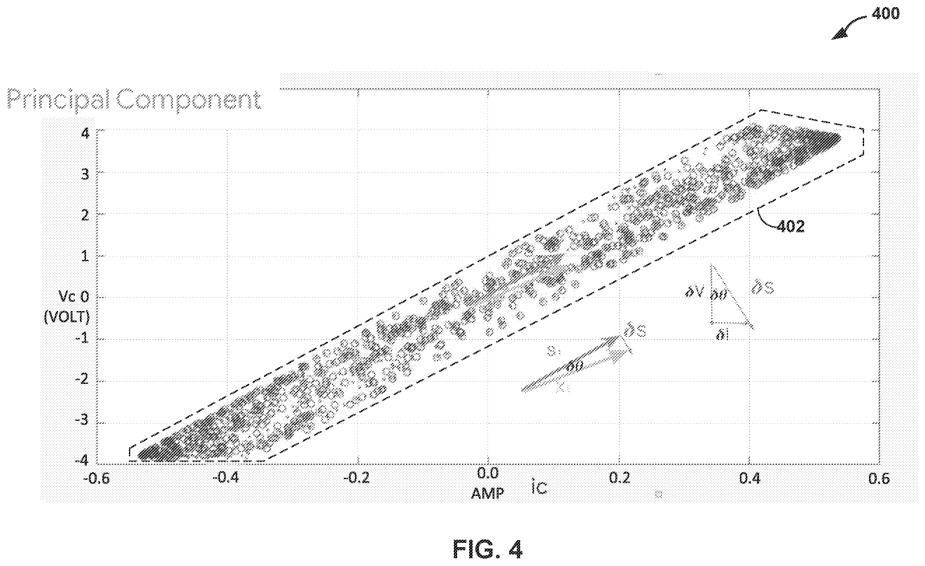

After obtaining the voltage measurements and the current measurements, transducer correction module 142 may identify at least one voltage measurement of the voltage measurements, and at least one current measurement of the current measurements representative of nonlinear vibration. The voltage measurement (which may be referred to as a “nonlinear voltage measurement”) may correspond (e.g., occur concurrently or as a result of the input voltage providing the basis for the voltage measurement) to the current measurement (which may be referred to as a “nonlinear current measurement”). The nonlinear voltage measurement may represent a voltage responsible for nonlinear vibration by the transducer, while the nonlinear current measurement may represent a current responsible for nonlinear vibration of the transducer. More information regarding identification of the nonlinear voltage measurement and the nonlinear current measurement is provided below with respect to FIGS. 3 and 4.

Transducer correction module 142 may next invoke a principal component analysis (PCA) unit 144, which represents a unit configured to perform a principal component analysis (PCA). PCA is used in a wide variety of applications and is often named differently for the different applications. For example, PCA may also be referred to as a Kahanen-Loeve transform (KLT) in signal processing, the hoteling transform in multivariate quality control, proper orthogonal decomposition (POD) in mechanical engineering, singular value decomposition (SVD), eigenvalue decomposition in linear algebra, and numerous other names in various other applications.

PCA unit 144 may perform PCA with respect to the nonlinear voltage and current measurements, where the nonlinear current t measurement may define an x-coordinate along the x-axis and the nonlinear voltage measurement may define a y-coordinate along the y-axis. The distribution of points of the nonlinear current-voltage measurements (effectively, x-coordinates and y-coordinates) may have a variance, where PCA may be thought of as fitting a 2-dimensional (in this instance, but more dimensions are possible) ellipsoid to the points, where each axis of the ellipsoid represents a principal component).

To find the axes of the ellipsoid, PCA unit 144 may subtract the mean of each variable of the points (e.g., the x-coordinate current measurement, and the y-coordinate voltage measure ter the data around the origin. PCA unit 144 may next compute the covariance matrix of the centered data and calculate the eigenvalues and corresponding eigenvectors of the covariance matrix. PCA unit 144 may next normalize each of the orthogonal eigenvectors to obtain unit vectors, where each mutually orthogonal, unit eigenvectors may represent an axis of the ellipsoid fitted to the points (which may also be referred to as the principal components representative of a maximum variation and a minimum variation—in this 2-dimensional instance—of the voltage across and the current through speaker 180).

PCA unit 144 may next determine, based on at least one of the principal components, an orientation slope of the above noted current-voltage distribution of points (which is formed from, and representative of, the voltage measurement and the current measurement). PCA unit 144 may output this orientation slope as an actual slope 145. Transducer correction module 142 may, responsive to receiving actual slope 145, compare actual slope 145 to target slope 147 (which may also be referred to as target orientation slope 147).

Transducer correction module 142 may obtain target slope 147 through machine learning applied during configuration of computing device 100, through manual configuration and testing during configuration of computing device 100, via subjective listening by a user or other operator of computing device 100, etc. In addition, transducer correction module 142 may continue to update target slope 147 over time via additional machine learning (e.g., either locally on computing device 100 or remotely via data transfers to cloud computing or other remote resources that are capable of adjusting target slope 147 to reflect wear-in of transducer 180 and other material aspects that impact the above noted nonlinear characteristics). Machine learning may utilize training data (e.g., experimental data from similar transducers to transducer 180 or actual measured data, such as previous principal components computed from previous voltage and current measurements over transducer 180) in a supervised learning, unsupervised learning, and/or reinforcement learning process. Target slope 147 may, in some examples, represent a linear slope that is in-line with the maximum principal component (e.g., the first principal component in the covariance matrix) where the minimum principal component (e.g., the second principal component in the covariance matrix) represents DC offset that may inject noise and leads to non-linear (with respect to the maximum principal component) vibration by speaker 180.

Transducer correction module 142 may then adapt or otherwise modify the input voltage driving transducer 180 to align the actual slope 145 with target slope 147 (e.g., by adjusting the input voltage up or down by some offset) to thereby reduce such nonlinear vibrations by speaker 180. In other words, transducer correction module 142 may modify, based on the principal components output by PCA unit 144 in the form of, as one example, actual slope 145, the input voltage to be applied across speaker 180 to reduce the above noted non-linear vibration by speaker 180 due to DC offset. As such, transducer correction module 142 may refrain from using a model to obtain predicted DC current offsets of speaker 180. Instead, transducer correction module 142 may modify, based on the principal component and not the predicted direct current offsets, the input voltage to be applied across speaker 180 to reduce nonlinear vibration by speaker 180.

In this way, computing device 100 may more efficiently identify DC offset (e.g., nonlinear excursion) and perform transducer excursion correction to reduce the impact of DC offset, thereby potentially reducing distortion and/or noise during playback of audio by the speaker 180 while also possibly protecting speaker 180 from damage. Further, as DC offset is identified without possibly resorting to complex DC offset modeling (e.g., by using a principal component analysis to identify the nonlinear slope representative of nonlinear excursions), computing device 100 may more efficiently (compared to the complex DC modeling) correct for transducer excursions in a manner that improves operation of computing device 100 itself (e.g., consumes less processor cycles, memory, memory bandwidth, and accompanying power).

While displayed as part of a single device in the example of FIG. 1, components of computing device 100 may, in some examples, be located within and/or as part of different devices. For instance, in some examples, some of or all the functionality of transducer correction module 142 may be located at the same or different computing systems. That is, in some examples, techniques of the present disclosure may be performed and utilized by a single computing device, while, in other examples, the techniques may be performed and/or utilized across a plurality of computing systems, such as a distributed or “cloud” computing system.

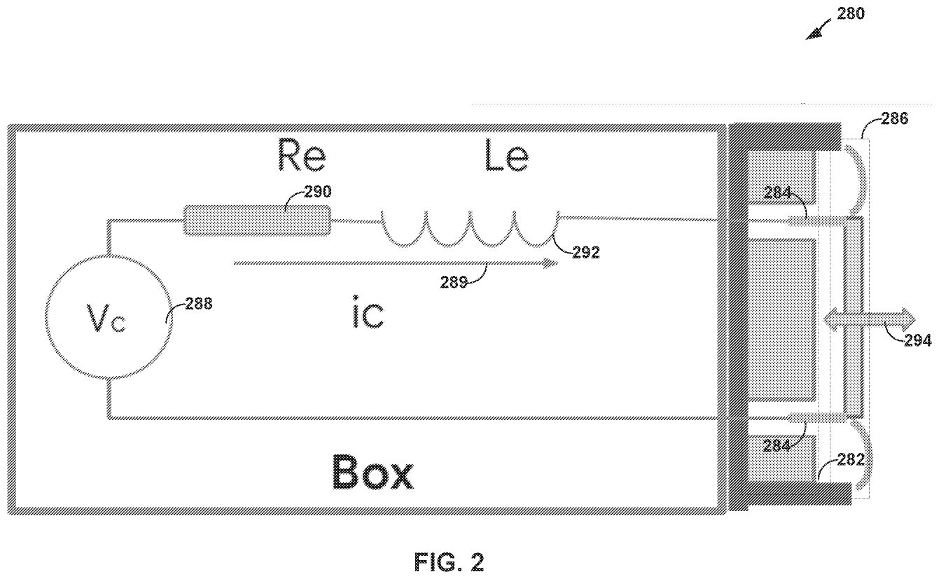

FIG. 2 is conceptual circuit diagram of an example transducer for which transducer correction may be performed in accordance with various aspects of the transducer exertion correction techniques described in this disclosure. A transducer 280 shown in the example of FIG. 2 may represent one example of transducer 180 shown in the example of FIG. 1. Moreover, transducer 280 is shown as a cross-sectional side view of a circular transducer in which various components should be assumed to encircle a circular housing (not denoted) and components as is common in the audio arts, and the circuit diagram represents intrinsic electrical characteristics of transducers 280 that are again common in the audio arts.

As shown in the example of FIG. 2, transducer 280 may include a magnet 282, a voice coil 284, and a cone 286 (which may also be referred to as a diagraph 286 along with a dust cap—which is assumed to be part of cone 286). Magnet 282 may represent a ferrite magnet, a neodymium magnet, or any other type of magnetic material that produces a magnetic field that interacts, via induction, with voice coil 284. Voice coil 284 may represent a wounded iron filament that conducts electricity to produce a temporary magnet (or, in other words, an electromagnet), which interacts with the magnetic field produced by magnet 282 to repel cone 286 outward from and inward to magnet 282 to produce sound waves (different pressures of air that the human auditory system interprets as sound).

Although described with respect to a magnetic coil setup for transducer 280, other types of speakers/transducers 280 may exhibit DC offset for different and/or similar reasons for which various aspects of the transducer excursion correction techniques described herein may attempt to correct. For example, various aspects of the techniques described in this disclosure may apply to piezoelectric transducers, planar magnetic transducers, electrostatic transducers, and the like.

In any event, the conceptual circuit diagram of speaker 280 further includes a representation of control voltage (Vc) 288 (which may be another way of referring to the above noted input voltage), a resistance (Re) 290, and an inductance (Le) 292. Control voltage 282 may represent a dedicated power source, including a transformer or other conversion hardware, that powers transducer 280 (which may merely represent a voltage potential across the circuit represented by transducer 280. In other words, transducer 280 represents an electrical circuit that transform electrical inputs into acoustic outputs (or, stated differently, sound waves). Control voltage 288 may be located outside of the housing or other physical assembly of transducer 280, where Vc thereby represents an application of a voltage across terminals that is provided via external means (e.g., communication channels 130 referring back to the example of FIG. 1).

Resistance 284 may represent an electrical resistance for the circuit forming transducer 280, which may operate in conjunction with inductance 292 to create a magnetic field via such induction through voice coil 284 in the presence of a magnetic field provided by magnets 282. That is, a particular current (ic) 289 resulting due to the electrical potential difference provided via control voltage 288 may create, via induction by way again of voice coil 284, a magnetic field that creates excursion (both inward and outward relative to magnets 282). Transducer 280 may, as noted above, have asymmetrical nonlinear characteristics, such as magnetic force factor (denoted as variable “BI(x)”) and suspension stiffness (denoted “k(x)”), where the variable “x” refers to speaker coil displacement 294 outward (positive value) and inward (negative value) relative to magnets 282. Such asymmetrical nonlinear characteristics may result in a DC offset in which cone 286 is displaced in one direction (e.g., outward in reference to magnets 282) more than another direction (e.g., inward—again in reference to magnets 282).

Transducer correction module 142 may obtain measurements of control voltage 288 and current 289 cither directly via actual measurements or indirectly, e.g., via electrical modeling of speaker 280—meaning a simplified electrical model, not a full DC offset model premised upon previous control voltages applied to transducer 280. In this way, transducer correction module 142 may obtain voltage and current measurements of transducer 280.

Transducer correction module 142 may next align voltage measurements with concurrent current measurements to formulate a table or other data structure representative of voltage measurements and concurrently approximated or measured current measurements to form what may be referred to as a current-voltage distribution. Such current-voltage distribution is shown in more detail with respect to the example of FIG. 3, but briefly, the current-voltage distribution may represent a table of current versus (vs.) voltage measurements (or possibly approximations where both the term “measurement” and “approximation” are assumed to be representative of current 289 through transducer 280 induced as a function of control voltage 288).

As the induction through voice coil 284 fluctuates to create excursions of cone 286, the above noted nonlinear characteristics may create nonlinear vibrations that impact current draw (e.g., changing current 289 due to nonlinear increases and decreases in magnetic force factor and stiffness). Such changing current 289 may be reflected as changing electrical impedance due to changes in induction due to the DC offset that results in the nonlinear vibrations. To correct for such DC offset, transducer correction module 142 may analyze the current-voltage distribution in order to identify nonlinear current-voltage points to which PCA unit 144 is invoked to apply PCA to determine the above noted principal components. PCA unit 144 may then determine, based on the at least one of the principal components, actual slope 145. Transducer correction module 144 may compare actual slope 145 to target slope 147 to modify control voltage 288 in order to steer transducer 280 back to linear operation in order to avoid nonlinear vibrations that may inject noise and other acoustic artifacts into the soundfield.

FIG. 3 is a diagram illustrating a graph of an example current-voltage distribution from which principal components are extracted to support various aspects of the transducer excursion correction techniques described in this disclosure. As shown in the example of FIG. 3, a graph 300 shows the linear current-voltage distribution as a band of points (BoP) 302 with each point having an x-axis current measurement (in amps) and a y-axis voltage measurement (in volts).

Transducer correction module 142 may invoke PCA unit 144 to apply PCA to BoP 302 to determine principal components X₁ and X₂ (which may also be denoted respectively as principal components 304A and 304B). PCA unit 144 may compute a target slope 147 for linear voltage-current points of BoP 302 in accordance with the following equations:

$$Var ( θ ) = \sum {[ {X}_{1} cos ( θ ) + {X}_{2} sin ( θ ) ]}^{2} , where$$

$$θ = 0.5 {tan}^{- 1} ( - 2 * \sum ( {X}_{1} * {X}_{2} ) / \sum ( {X}_{2}^{2} - {X}_{1}^{2} ) ) with respect to \frac{d Var ( θ )}{d θ} = 0.$$

In the above equation, “Var” denotes variance of theta (θ) which is shown as angle 306 in graph 300 and is determined according to the second equation listed above. Although described with respect to linear voltage-current points to identify target slope 147 (which again can be further adapted and refined by training of machine learning), PCA unit 144 may utilize the same process to identify actual slope 145 for nonlinear current-voltage points, which is shown in more detail with respect to the example of FIG. 4.

PCA unit 144 may, in other words, specify the orientations or components of maximum (X₁) and minimum (X₂) variation by consistently calculating the historically observed data of coil current (ic) and input voltage with angle θ in terms of minimum mean square error analysis (referring to the delta variance—dVar—of angle θ divided by delta angle θ being equal to zero). PCA unit 144 may calculate the electrical impedance, which is the same as the slope or tan(θ) of the Vc-ic curve. Because the electrical impedance is different in linear and nonlinear speaker vibration, transducer correction module 142 may mitigate the nonlinear excursion by consistently observing the variation of the angle θ and steering the variation of the angle θ to coincide with the linear angle θ₀ (linear impedance) with input voltage.

FIG. 4 is another diagram illustrating a graph of an example current-voltage distribution from which principal components are extracted to support various aspects of the transducer excursion correction techniques described in this disclosure. As shown in the example of FIG. 4, a graph 400 shows the current-voltage distribution as a band of points (BoP) 342 with each point having an x-axis current measurement (in amps) and a y-axis voltage measurement (in volts). As noted above with respect to the example of FIG. 3, transducer correction module 142 may distinguish between points representative of linear and nonlinear speaker vibration using the electrical impedance (which again is represented by the slope of each respective set of linear and nonlinear current-voltage points—which is equivalent to tan(θ) for each of the respective sets of linear and nonlinear current-voltage points).

Transducer correction module 142 may determine an angle θ₀ for the linear voltage-current points (shown as dots) and an angle θ for the nonlinear voltage-current points (shown as circles). Transducer correction module 142 may determine the angle θ₀ between a line perpendicular to the x-axis from the origin of the ellipsoid (e.g., the starting point of target slope 147, which is denoted as S₁ in the example of FIG. 4) and the target slope 147. Transducer correction module 142 may determine the angle θ between a line perpendicular to the x-axis from the origin of the ellipsoid (e.g., the starting point of the maximum principal component X₁,) and the principal component X₁. Transducer correction module 142 may next determine the difference between angle θ₀ and angle θ (which is shown as δθ), which the projected variation δS being the distance between the end points of linear component S₁ and nonlinear component X₁ (both of which may represent vectors).

Transducer correction module 142 may next determine a compensated voltage δV and a compensated current δI as the projection of such variation δI between nonlinear component X₁ and linear component S₁ with regard to the angle δθ in the current and voltage direction. As noted above, the linear component S₁ (which is another way to refer to target slope 147) can be adapted and refined by training of machine learning.

In this respect, transducer correction module 142 may determine an angle θ relative to the x-axis of a current-voltage distribution representative of current measurements relative to the voltage measurements, where transducer correction module 142 may determine such angle, in some examples, based on the principle component X₁. Transducer correction module 142 may then determine, based on the angle, electrical impedance of the current-voltage distribution (e.g., by computing the tangent of the angle). Based on the electrical impedance, transducer correction module 142 may determine the nonlinear voltage measurements and the nonlinear current measurements.

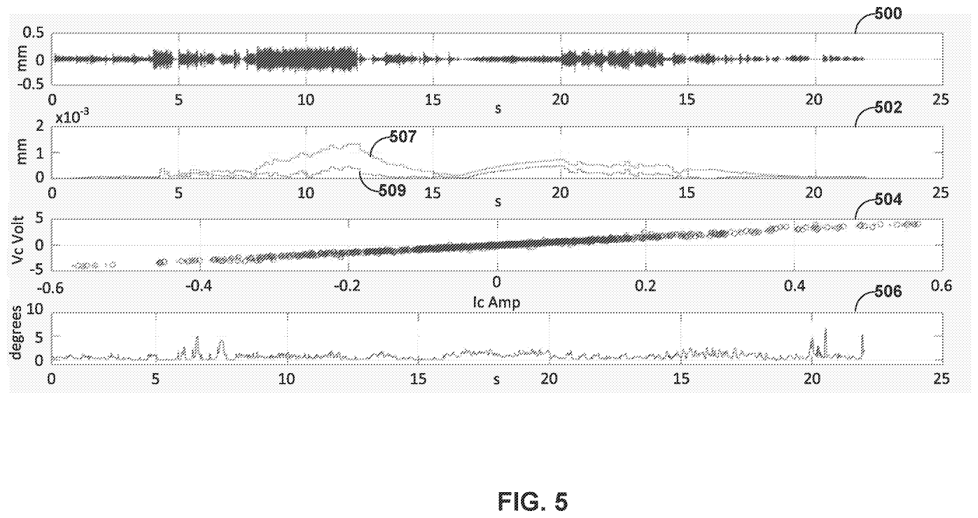

FIG. 5 is a diagram illustrating four graphs showing example results of performing various aspects of the transducer excursion correction techniques described in this disclosure. A first graph 500 shows the real-time signal in terms of excursion distance (in millimeters—mm) over a period of time (e.g., 0 to 35 seconds—s). A second graph 502 shows linear excursions distance 507 and non-linear excursion distance 509 (in mm, but times 10⁻³). A third graph 504 shows a current-voltage distribution of non-linear (circle) points and linear points (dots). A fourth graph 506 shows the steering angle δθ in degrees over the period of time (e.g., 0 to 35 seconds) that is determined by transducer correction module 142.

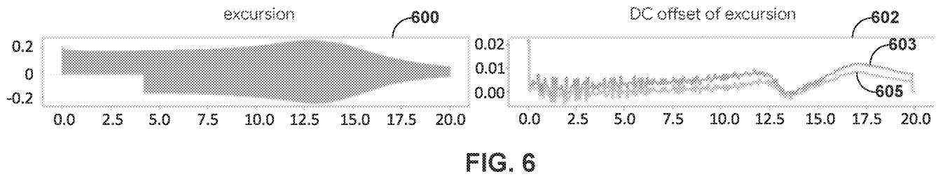

FIG. 6 is a diagram illustrating two graphs showing additional example results of performing various aspects of the transducer excursion correction techniques described in this disclosure. Graph 600 and 602 show measurements of excursion and DC offset of excursion from a chirp ranging from a frequency of 100 hertz (Hz) to 20 kilohertz (KHz) over a period of time (e.g., 20 seconds). Graph 600 shows the excursion distance (in mm) measured at speaker 180 over the period of time, while graph 602 shows the DC offset of excursion that would have occurred when not adjusting the input voltage (as line 603) and the DC offset of excursion that occurs when adjusting the input voltage in accordance with various aspects of the transducer excursion correction techniques described in this disclosure (as line 605). As shown in graph 602, line 603 produces more DC offset of excursion in certain instances compared to line 605, potentially validating the above-described transducer excursion correction techniques.

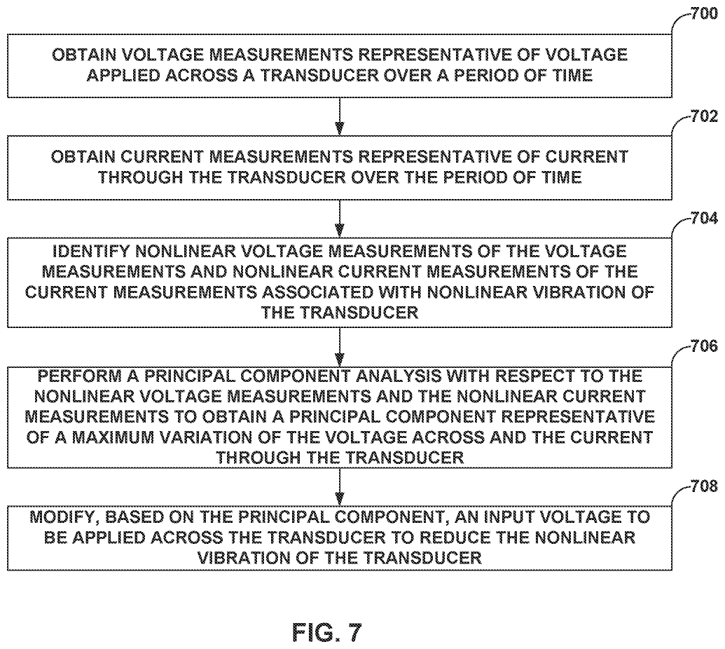

FIG. 7 is a flowchart illustrating exemplary operation of the computing device shown in FIG. 1 in performing various aspects of the transducer excursion correction techniques. Computing device 100 may initially invoke transducer correction module 142, which may obtain voltage measurements representative of a voltage across transducer 180 over a period of time (700). Transducer correction module 142 may also obtain the current measurement representative of a current through transducer 180, again either from storage components 140 and/or directly from speaker 180, for the same period of time and in a similar manner to how the voltage measurements are obtained (702).

After obtaining the voltage measurements and the current measurements, transducer correction module 142 may identify nonlinear voltage measurements of the voltage measurements, and nonlinear current measurements of the current measurements that are associated with nonlinear vibration of transducer 180 (704). Transducer correction module 142 may next invoke a principal component analysis (PCA) unit 144, which represents a unit configured to perform a principal component analysis (PCA). PCA unit 144 may perform PCA with respect to the nonlinear voltage and current measurements to obtain principal component X₁ representative of a maximum variation of the voltage across and the current through transducer 180 (706).

PCA unit 144 may next determine, based on at least one of the principal components, an orientation slope of the above noted current-voltage distribution of points (which is formed from, and representative of, the voltage measurement and the current measurement) PCA unit 144 may output this orientation slope as an actual slope 145. Transducer correction module 142 may, responsive to receiving actual slope 145, compare actual slope 145 to target slope 147 (which may also be referred to as target orientation slope 147).

Transducer correction module 142 may obtain target slope 147 through machine learning applied during configuration of computing device 100, through manual configuration and testing during configuration of computing device 100, via subjective listening by a user or other operator of computing device 100, etc. In addition, transducer correction module 142 may continue to update target slope 147 over time via additional machine learning (e.g., either locally on computing device 100 or remotely via data transfers to cloud computing or other remote resources that are capable of adjusting target slope 147 to reflect wear-in of transducer 180 and other material aspects that impact the above noted nonlinear characteristics).

Transducer correction module 142 may then adapt or otherwise modify the input voltage driving transducer 180 to align the actual slope 145 with target slope 147 (e.g., by adjusting the input voltage up or down by some offset) to thereby reduce such nonlinear vibrations by speaker 180. In other words, transducer correction module 142 may modify, based on the principal components output by PCA unit 144 in the form of, as one example, actual slope 145, the input voltage to be applied across transducer 180 to reduce the above noted non-linear vibration by transducer 180 due to DC offset (708). As such, transducer correction module 142 may refrain from using a model to obtain predicted DC current offsets of speaker 180. Instead, transducer correction module 142 may modify, based on the principal component and not the predicted direct current offsets, the input voltage to be applied across speaker 180 to reduce nonlinear vibration by speaker 180.

In this respect, various aspects of the techniques may enable the following clauses.

Clause 1. A method comprising: obtaining, by one or more processors of a computing device, a plurality of voltage measurements representative of voltage applied across a transducer over a period of time; obtaining, by the one or more processors, a plurality of current measurements representative of current through the transducer over the period of time; identifying, by the one or more processors, at least one first voltage measurement of the plurality of voltage measurements and at least one first current measurement of the plurality of current measurements associated with nonlinear vibration of the transducer; performing, by the one or more processors, a principal component analysis with respect to the at least one first voltage measurement and the at least one first current measurement to obtain a principal component representative of a maximum variation of the voltage across and the current through the transducer; and modifying, by the one or more processors, and based on the principal component, an input voltage to be applied across the transducer to reduce the nonlinear vibration of the transducer.

Clause 2. The method of clause 1, wherein modifying the voltage comprises: determining, based on the principal component, an orientation slope of a current-voltage distribution representative of the at least first voltage measurement and the at least one first current measurement; comparing the orientation slope to a target orientation slope to identify an angle deviation; and modifying, based on the angle deviation, the input voltage to be applied across the transducer to reduce the nonlinear vibration by the transducer.

Clause 3. The method of clause 2, wherein the target orientation slope is determined via application of machine learning to previous principal component obtained via application of principal component analysis to previous voltage measurements and previous current measurements that produce linear vibration by the transducer.

Clause 4. The method of any combination of clauses 1-3, wherein the transducer produces the nonlinear vibration as a result of a direct current offset due to one or more of a non-linear magnetic force factor and a suspension stiffness supporting a coil of the transducer.

Clause 5. The method of any combination of clauses 1-4, wherein modifying, based on the principal component, the input voltage comprises: refraining from using a model to obtain predicted direct current offsets of the transducer; and modifying, based on the principal component and not the predicted direct current offsets, the input voltage to be applied across the transducer to reduce nonlinear vibration by the transducer.

Clause 6. The method of any combination of clauses 1-5, wherein identifying, by the one or more processors, the at least one first voltage measurement of the plurality of voltage measurements and the at least one first current measurement of the plurality of current measurements associated with nonlinear vibration of the transducer includes: determining an angle relative to an x-axis of a current-voltage distribution representative of the plurality of current measurements relative to the plurality of voltage measurements; determining, based on the angle, electrical impedance of the current-voltage distribution, and identifying, based on the electrical impedance, the at least one first voltage measurement and the at least one first current measurement.

Clause 7. The method of clause 6, wherein determining the angle comprises determining, based on the principal component, the angle relative to the x-axis.

Clause 8 The method of any combination of clauses 6 and 7, wherein determining the electrical impedance comprises computing a tangent of the angle to obtain the electrical impedance.

Clause 9. The method of any combination of clauses 1-8, wherein the computing device comprises a mobile device that includes the transducer within a housing of the mobile device.

Clause 10. A computing device comprising: a memory configured to store a plurality of voltage measurements representative of a voltage across a transducer over a period of time and a plurality of current measurements representative of current through the transducer over the period of time, and one or more processors configured to: identify at least one first voltage measurement of the plurality of voltage measurements and at least one first current measurement of the plurality of current measurements associated with nonlinear vibration of the transducer; perform a principal component analysis with respect to the at least one first voltage measurement and the at least one first current measurement to obtain a principal component representative of a maximum variation of the voltage across and the current through the transducer; and modify, based on the principal component, an input voltage to be applied across the transducer to reduce the nonlinear vibration of the transducer.

Clause 11. The computing device of clause 10, wherein the one or more processors are, when configured to modify the voltage, configured to: determine, based on the principal component, an orientation slope of a current-voltage distribution representative of the at least first voltage measurement and the at least one first current measurement; compare the orientation slope to a target orientation slope to identify an angle deviation; and modify, based on the angle deviation, the input voltage to be applied across the transducer to reduce the nonlinear vibration by the transducer.

Clause 12. The computing device of clause 12, wherein the target orientation slope is determined via application of machine learning to previous principal component obtained via application of principal component analysis to previous voltage measurements and previous current measurements that produce linear vibration by the transducer.

Clause 13. The computing device of any combination of clauses 10-12, wherein the transducer produces the nonlinear vibration as a result of a direct current offset due to one or more of a non-linear magnetic force factor and a suspension stiffness supporting a coil of the transducer.

Clause 14. The computing device of any combination of clauses 10-13, wherein the one or more processors are, when configured to modify the input voltage, configured to: refrain from using a model to obtain predicted direct current offsets of the transducer; and modify, based on the principal component and not the predicted direct current offsets, the input voltage to be applied across the transducer to reduce nonlinear vibration by the transducer.

Clause 15. The computing device of any combination of clauses 10-15, wherein the one or more processors are, when configured to identify the at least one first voltage measurement of the plurality of voltage measurements and the at least one first current measurement of the plurality of current measurements, configured to: determine an angle relative to an x-axis of a current-voltage distribution representative of the plurality of current measurements relative to the plurality of voltage measurements; determine, based on the angle, electrical impedance of the current-voltage distribution; and identify, based on the electrical impedance, the at least one first voltage measurement and the at least one first current measurement.

Clause 16. The computing device of clause 15, wherein the one or more processors are, when configured to determine the angle, determine, based on the principal component, the angle relative to the x-axis.

Clause 17. The computing device of any combination of clauses 15 and 16, wherein the one or more processors are, when configured to determine the electrical impedance, compute a tangent of the angle to obtain the electrical impedance.

Clause 18. The computing device of any combination of clauses 10-17, wherein the computing device comprises a mobile device that includes the transducer within a housing of the mobile device.

Clause 19. A non-transitory computer-readable storage medium having stored thereon instructions that, when executed, cause one or more processors of a computing device to: obtain a plurality of voltage measurements representative of a voltage across a transducer over a period of time; obtain a plurality of current measurements representative of current through the transducer over the period of time; identify at least one first voltage measurement of the plurality of voltage measurements and at least one first current measurement of the plurality of current measurements associated with nonlinear vibration of the transducer; perform a principal component analysis with respect to the at least one first voltage measurement and the at least one first current measurement to obtain a principal component representative of a maximum variation of the voltage across and the current through the transducer; and modify, based on the principal component, an input voltage to be applied across the transducer to reduce the nonlinear vibration of the transducer.

Clause 20. The non-transitory computer-readable storage medium of clause 19, wherein the instructions that cause the one or more processors to modify the voltage, comprise instruction that cause the one or more processors to: determine, based on the principal component, an orientation slope of a current-voltage distribution representative of the at least first voltage measurement and the at least one first current measurement; compare the orientation slope to a target orientation slope to identify an angle deviation; and modify, based on the angle deviation, the input voltage to be applied across the transducer to reduce the nonlinear vibration by the transducer.

In one or more examples, the functions described may be implemented in hardware, software, firmware, or any combination thereof. If implemented in software, the functions may be stored on or transmitted over, as one or more instructions or code, a computer-readable medium and executed by a hardware-based processing unit. Computer-readable media may include computer-readable storage media, which corresponds to a tangible medium such as data storage media, or communication media, which includes any medium that facilitates transfer of a computer program from one place to another, e.g., according to a communication protocol. In this manner, computer-readable media generally may correspond to (1) tangible computer-readable storage media, which is non-transitory or (2) a communication medium such as a signal or carrier wave. Data storage media may be any available media that can be accessed by one or more computers or one or more processors to retrieve instructions, code and/or data structures for implementation of the techniques described in this disclosure. A computer program product may include a computer-readable storage medium.

By way of example, and not limitation, such computer-readable storage media can comprise RAM, ROM, EEPROM, CD-ROM or other optical disk storage, magnetic disk storage, or other magnetic storage devices, flash memory, or any other medium that can be used to store desired program code in the form of instructions or data structures and that can be accessed by a computer. Also, any connection is properly termed a computer-readable medium. For example, if instructions are transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. It should be understood, however, that computer-readable storage media and data storage media do not include connections, carrier waves, signals, or other transient media, but are instead directed to non-transient, tangible storage media. Disk and disc, as used herein, includes compact disc (CD), laser disc, optical disc, digital versatile disc (DVD), floppy disk and Blu-ray disc, where disks usually reproduce data magnetically, while discs reproduce data optically with lasers. Combinations of the above should also be included within the scope of computer-readable media.

Instructions may be executed by one or more processors, such as one or more digital signal processors (DSPs), general purpose microprocessors, application specific integrated circuits (ASICs), field programmable gate arrays (FPGAs), or other equivalent integrated or discrete logic circuitry. Accordingly, the term “processor,” as used herein may refer to any of the foregoing structures or any other structure suitable for implementation of the techniques described herein. In addition, in some aspects, the functionality described herein may be provided within dedicated hardware and/or software modules. Also, the techniques could be fully implemented in one or more circuits or logic elements.

The techniques of this disclosure may be implemented in a wide variety of devices or apparatuses, including a wireless handset, an integrated circuit (IC) or a set of ICs (e.g., a chip set). Various components, modules, or units are described in this disclosure to emphasize functional aspects of devices configured to perform the disclosed techniques, but do not necessarily require realization by different hardware units. Rather, as described above, various units may be combined in a hardware unit or provided by a collection of interoperative hardware units, including one or more processors as described above, in conjunction with suitable software and/or firmware.

Various examples have been described. These and other examples are within the scope of the following claims

What is claimed is:

1. A method comprising:
obtaining, by one or more processors of a computing device, a plurality of voltage measurements representative of voltage applied across a transducer over a period of time,
obtaining, by the one or more processors, a plurality of current measurements representative of current through the transducer over the period of time;
identifying, by the one or more processors, at least one first voltage measurement of the plurality of voltage measurements and at least one first current measurement of the plurality of current measurements associated with nonlinear vibration of the transducer;
performing, by the one or more processors, a principal component analysis with respect to the at least one first voltage measurement and the at least one first current measurement to obtain a principal component representative of a maximum variation of the voltage across and the current through the transducer; and
modifying, by the one or more processors, and based on the principal component, an input voltage to be applied across the transducer to reduce the nonlinear vibration of the transducer.

2. The method of claim 1, wherein modifying the input voltage comprises:
determining, based on the principal component, an orientation slope of a current-voltage distribution including the at least one first voltage measurement and the at least one first current measurement;
comparing the orientation slope to a target orientation slope to identify an angle deviation; and
modifying, based on the angle deviation, the input voltage to be applied across the transducer to reduce the nonlinear vibration by the transducer.

3. The method of claim 2, wherein the target orientation slope is determined via application of machine learning to at least one previous principal component obtained via application of principal component analysis to previous voltage measurements and previous current measurements that produce linear vibration by the transducer.

4. The method of claim 1, wherein the transducer produces the nonlinear vibration as a result of a direct current offset due to one or more of a non-linear magnetic force factor and a suspension stiffness supporting a coil of the transducer.

5. The method of claim 1, wherein modifying, based on the principal component, the input voltage comprises:
refraining from using a model to obtain predicted direct current offsets of the transducer; and
modifying, based on the principal component and not the predicted direct current offsets, the input voltage to be applied across the transducer to reduce nonlinear vibration by the transducer.

6. The method of claim 1, wherein identifying, by the one or more processors, the at least one first voltage measurement of the plurality of voltage measurements and the at least one first current measurement of the plurality of current measurements associated with nonlinear vibration of the transducer includes:
determining an angle relative to an x-axis of a current-voltage distribution representative of the plurality of current measurements relative to the plurality of voltage measurements;
determining, based on the angle, electrical impedance of the current-voltage distribution; and
identifying, based on the electrical impedance, the at least one first voltage measurement and the at least one first current measurement.

7. The method of claim 6, wherein determining the angle comprises determining, based on the principal component, the angle relative to the x-axis.

8. The method of claim 6, wherein determining the electrical impedance comprises computing a tangent of the angle to obtain the electrical impedance.

9. The method of claim 1, wherein the computing device comprises a mobile device that includes the transducer within a housing of the mobile device.

10. A computing device comprising:
a memory configured to store a plurality of voltage measurements representative of a voltage across a transducer over a period of time and a plurality of current measurements representative of current through the transducer over the period of time; and
one or more processors configured to:
identify at least one first voltage measurement of the plurality of voltage measurements and at least one first current measurement of the plurality of current measurements associated with nonlinear vibration of the transducer;
perform a principal component analysis with respect to the at least one first voltage measurement and the at least one first current measurement to obtain a principal component representative of a maximum variation of the voltage across and the current through the transducer; and
modify, based on the principal component, an input voltage to be applied across the transducer to reduce the nonlinear vibration of the transducer.

11. The computing device of claim 10, wherein the one or more processors are, when configured to modify the input voltage, configured to:
determine, based on the principal component, an orientation slope of a current-voltage distribution including the at least one first voltage measurement and the at least one first current measurement,
compare the orientation slope to a target orientation slope to identify an angle deviation; and
modify, based on the angle deviation, the input voltage to be applied across the transducer to reduce the nonlinear vibration by the transducer.

12. The computing device of claim 11, wherein the target orientation slope is determined via application of machine learning to previous principal component obtained via application of principal component analysis to previous voltage measurements and previous current measurements that produce linear vibration by the transducer.

13. The computing device of claim 10, wherein the transducer produces the nonlinear vibration as a result of a direct current offset due to one or more of a non-linear magnetic force factor and a suspension stiffness supporting a coil of the transducer.

14. The computing device of claim 10, wherein the one or more processors are, when configured to modify the input voltage, configured to:
refrain from using a model to obtain predicted direct current offsets of the transducer; and
modify, based on the principal component and not the predicted direct current offsets, the input voltage to be applied across the transducer to reduce nonlinear vibration by the transducer.

15. The computing device of claim 10, wherein the one or more processors are, when configured to identify the at least one first voltage measurement of the plurality of voltage measurements and the at least one first current measurement of the plurality of current measurements, configured to:
determine an angle relative to an x-axis of a current-voltage distribution representative of the plurality of current measurements relative to the plurality of voltage measurements,
determine, based on the angle, electrical impedance of the current-voltage distribution; and
identify, based on the electrical impedance, the at least one first voltage measurement and the at least one first current measurement.

16. The computing device of claim 15, wherein the one or more processors are, when configured to determine the angle, determine, based on the principal component, the angle relative to the x-axis.

17. The computing device of claim 15, wherein the one or more processors are, when configured to determine the electrical impedance, compute a tangent of the angle to obtain the electrical impedance.

18. The computing device of claim 10, wherein the computing device comprises a mobile device that includes the transducer within a housing of the mobile device.

19. A non-transitory computer-readable storage medium having stored thereon instructions that, when executed, cause one or more processors of a computing device to:
obtain a plurality of voltage measurements representative of a voltage across a transducer over a period of time;
obtain a plurality of current measurements representative of current through the transducer over the period of time;
identify at least one first voltage measurement of the plurality of voltage measurements and at least one first current measurement of the plurality of current measurements associated with nonlinear vibration of the transducer;
perform a principal component analysis with respect to the at least one first voltage measurement and the at least one first current measurement to obtain a principal component representative of a maximum variation of the voltage across and the current through the transducer; and
modify, based on the principal component, an input voltage to be applied across the transducer to reduce the nonlinear vibration of the transducer.

20. The non-transitory computer-readable storage medium of claim 19, wherein the instructions that cause the one or more processors to modify the input voltage, comprise instruction that cause the one or more processors to:
determine, based on the principal component, an orientation slope of a current-voltage distribution including the at least nonlinear voltage measurement and the at least one nonlinear current measurement;
compare the orientation slope to a target orientation slope to identify an angle deviation; and
modify, based on the angle deviation, the input voltage to be applied across the transducer to reduce the nonlinear vibration by the transducer.
